(19) United States
(12) Patent Application Publication
(10) Pub. No.: US 2004/0245985 A1
(43) Pub. Date: Dec. 9, 2004

(54) apparatus for monitoring changes in a magnetic field

(76) Inventors: Glenn Mayfield, Garland, TX (US); Chuanyang Wang, Richardson, TX (US); Indumini Ranmuthu, Plano, TX (US); Bryan E. Bloodworth, Irving, TX (US); James Nodar, Dallas, TX (US)

Correspondence Address: TEXAS INSTRUMENTS INCORPORATED, P O BOX 655474, M/S 3999, DALLAS, TX, 75265

(21) Appl. No.: 10/453,319

(22) Filed: Jun. 3, 2003

(51) Int. Cl. G01R 33/12; G01R 33/02

(52) U.S. Cl. 324/252; 324/210

(57) ABSTRACT

An apparatus for monitoring changes in a magnetic field using a magneto-resistive device situated in the field includes a first and second input locus coupled with the magneto-resistive device. An amplifier means for amplifying electrical signals has input terminals and output terminals. A first input terminal is coupled with the first input locus with a first capacitor coupled in series between the first input locus and the first input terminal. A second input terminal is coupled with the second input locus with a second capacitor coupled in series between the second input locus and the second input terminal. The apparatus receives a bias current at the first input locus that cooperates with the magneto-resistive element to affect electrical potential at the first input locus. The amplifier device presents at least one output signal at the output terminals indicating changes in the magnetic field.

### BACKGROUND OF THE INVENTION

The present invention is directed to apparatuses for monitoring changes in magnetic fields, and especially to such apparatuses employed in magnetic storage read devices, sometimes referred to as read heads.

In preamplifiers associated with monitoring changes in magnetic fields, such as read heads for reading information from a rotating magnetic storage disk, a magneto-resistive device is situated within the magnetic field to sense magnetic properties in the field. An example of such a magneto-resistive device is a magnetic resistivity device that exhibits changes in resistance with changes in a magnetic field in which it is located. The magneto-resistive device is preferably located in close proximity with the rotating disk of a magnetic storage device in order to accurately monitor changes in the magnetic field of the disk that comprise data indicators. A danger with such a close proximal relation between the magneto-resistive device and the rotating disk is that if too much potential difference is present between the two components, arcing may occur between the components thereby damaging at least one of the components.

In the past the need for keeping voltage levels at the magneto-resistive device low had a tendency to interfere with operation of the amplifier device of the preamplifier apparatus to which the magneto-resistive device is coupled. This tendency existed because the amplifier device requires a predetermined voltage potential to ensure reliable operation of its internal transistor components. The voltage potential required to assure reliable operation of transistor components within the amplifier device is significantly greater than the potential at which the magneto-resistive device should be maintained.

This problem was overcome in the prior art by using a fully differential amplifier circuit arrangement in which the amplifier device is coupled with a power supply that provides both a positive supply voltage and a negative supply voltage. By such an arrangement, a circuit designer can substantially independently control voltage potential across transistor components within an amplifier and voltage potential at a circuit locus coupled with the amplifier device.

With the current trend in industry toward cost savings in circuit construction and toward smaller, more compact products, such fully differential circuit construction has been supplanted in some products by a single supply circuit arrangement. A single supply circuit arrangement provides supply voltage only to one supply voltage input terminal (for example, and preferably the positive supply voltage input terminal) of an amplifier device. The other supply voltage terminal (for example, and preferably the negative supply voltage terminal) is connected to ground potential. Such single supply circuit arrangements provide advantages in their being less expensive to construct, less complex in their layout, requiring fewer connections and they may be produced using smaller semiconductor dies. However, such a single supply arrangement provides no independent control of voltage potential across transistor components within an amplifier and voltage potential at a circuit locus coupled with the amplifier device (e.g., a circuit locus at which potential at a magneto-resistive device is controlled).

There is a need for an apparatus for monitoring changes in a magnetic field that can be configured in a single supply circuit arrangement and effect substantially independent control of voltage across transistor components within an amplifier device and voltage potential at a circuit locus coupled with the amplifier device.

### SUMMARY OF THE INVENTION

An apparatus for monitoring changes in a magnetic field using a magneto-resistive device situated in the field includes a first and second input locus coupled with the magneto-resistive device. An amplifier means for amplifying electrical signals has input terminals and output terminals. A first input terminal is coupled with the first input locus with a first capacitor coupled in series between the first input locus and the first input terminal. A second input terminal is coupled with the second input locus with a second capacitor coupled in series between the second input locus and the second input terminal. The apparatus receives a bias current at the first input locus that cooperates with the magneto-resistive element to affect electrical potential at the first input locus. The amplifier device presents at least one output signal at the output terminals indicating changes in the magnetic field.

It is, therefore, an object of the present invention to provide an apparatus for monitoring changes in a magnetic field that can be configured in a single supply circuit arrangement and effect substantially independent control of voltage across transistor components within an amplifier device and voltage potential at a circuit locus coupled with the amplifier device.

Further objects and features of the present invention will be apparent from the following specification and claims when considered in connection with the accompanying drawings, in which like elements are labeled using like reference numerals in the various figures, illustrating the preferred embodiments of the invention.

### BRIEF DESCRIPTION OF THE DRAWINGS

FIG. 1 is an electrical schematic diagram illustrating a prior art fully differential preamplifier for a magnetic read head for a disk drive.

FIG. 2 is an electrical schematic diagram illustrating a prior art single supply preamplifier for a magnetic read head for a disk drive.

FIG. 3 is an electrical schematic diagram illustrating a novel single supply preamplifier for a magnetic read head for a disk drive configured according to the teachings of the present invention.

FIG. 4 is an electrical schematic diagram illustrating an equivalent circuit for a portion of the novel single supply preamplifier illustrated in FIG. 3.

FIG. 5 is a graphic representation of the sensitivity responses of a prior art single supply preamplifiers and a novel single supply preamplifier configured according to the teachings of the present invention.

### DETAILED DESCRIPTION OF THE PREFERRED EMBODIMENT

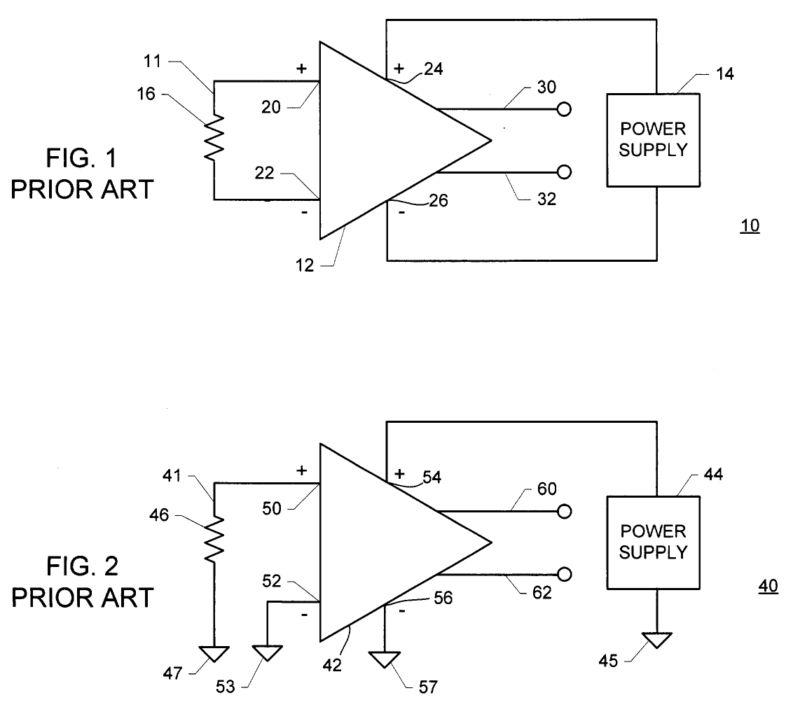

FIG. 1 is an electrical schematic diagram illustrating a prior art fully differential preamplifier for a magnetic read head for a disk drive. In FIG. 1, a preamplifier apparatus 10 includes an amplifier 12, a power supply circuit 14 and a magneto-resistive device 16. An example of such a magneto-resistive device is a magnetic resistivity device that exhibits changes in resistance with changes in a magnetic field in which it is located. Amplifier 12 has a positive signal input terminal 20 and a negative signal input terminal 22. Amplifier 12 also has a positive supply terminal 24 and a negative supply terminal 26. Amplifier 12 has output terminals 30, 32 at which signals are presented that are representative of signals received at signal input terminals 20, 22. Power supply circuit 14 is coupled with both supply terminals 24, 26 so that power supply circuit 14 provides a positive supply signal to positive supply terminal 24 and provides a negative supply signal to negative supply terminal 26. Voltage potential at a circuit locus 11, adjacent to magneto-resistive device 16, is preferably kept at a voltage level low enough to preclude arcing between magneto-resistive device 16 and an adjacent magnetic component, such as a magnetic disk of a data storage device (not shown in FIG. 1). Maintaining voltage potential at circuit locus 11 at a first potential level that is significantly lower than the potential required at signal input terminal 20 may be effected in preamplifier apparatus 10 by adjusting the negative supply signal provided to negative supply terminal 26.

FIG. 2 is an electrical schematic diagram illustrating a prior art single supply preamplifier for a magnetic read head for a disk drive. In FIG. 2, a preamplifier apparatus 40 includes an amplifier 42, a power supply circuit 44 and a magneto-resistive device 46. An example of such a magneto-resistive device is a magnetic resistivity device that exhibits changes in resistance with changes in a magnetic field in which it is located. Amplifier 42 has a positive signal input terminal 50 and a negative signal input terminal 52. Amplifier 42 also has a positive supply terminal 54 and a negative supply terminal 56. Amplifier 42 has output terminals 60, 62 at which signals are presented that are representative of signals received at signal input terminals 50, 52.

Magneto-resistive device 46 is coupled between positive signal input terminal 50 and ground potential at ground locus 47. Negative signal input terminal 52 is coupled with ground potential at ground locus 53. Power supply circuit 44 is coupled with ground potential at ground locus 45. Power supply circuit 44 is coupled with positive supply terminal 54 so that power supply circuit 44 provides a positive supply signal to positive supply terminal 54. Negative supply terminal 56 is coupled to ground potential at ground locus 57. No negative supply signal is supplied to amplifier 42 by power supply circuit 44. Voltage potential at a circuit locus 41, electrically adjacent to magneto-resistive device 46 and to positive signal input terminal 50, is preferably kept at a voltage level low enough to preclude arcing between magneto-resistive device 46 and an adjacent magnetic component, such as a magnetic disk of a data storage device (not shown in FIG. 2).

Maintaining voltage potential at circuit locus 41 at a sufficiently low potential to avoid arcing between magneto-resistive device 46 and a magnetic disk of a data storage device disadvantageously affects operation of amplifier 42 because circuit locus 41 is electrically common with positive signal input terminal 50. The level at which circuit locus 41 must be maintained results in having to bias internal components of amplifier 42 in a manner that establishes a low pass pole that limits maximum operational frequency of apparatus 40 to a lower value than is achievable in a fully differential amplifier (e.g., amplifier 10; FIG. 1).

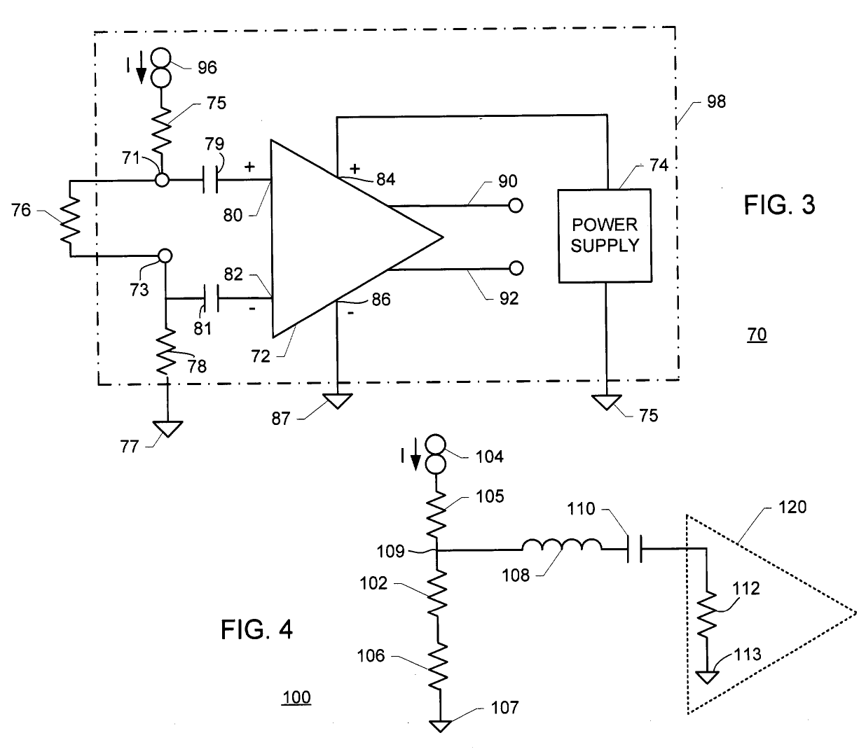

FIG. 3 is an electrical schematic diagram illustrating a novel single supply preamplifier for a magnetic read head for a disk drive configured according to the teachings of the present invention. In FIG. 3, a preamplifier apparatus 70 includes an amplifier 72, a power supply circuit 74 and a magneto-resistive device 76. An example of such a magneto-resistive device is a magnetic resistivity device that exhibits changes in resistance with changes in a magnetic field in which it is located. Amplifier 72 has a positive signal input terminal 80 and a negative signal input terminal 82. Amplifier 72 also has a positive supply terminal 84 and a negative supply terminal 86. Amplifier 72 has output terminals 90, 92 at which signals are presented that are representative of signals received at signal input terminals 80, 82.

Magneto-resistive device 76 is coupled between a first circuit locus 71 and a second circuit locus 73. First circuit locus 71 is coupled with positive signal input terminal 50 via a direct current (DC) blocking capacitor 79. Second circuit locus 73 is coupled with negative signal input terminal 82 via a DC blocking capacitor 81. Second circuit locus 73 is also coupled with ground potential at ground locus 77 via a bias or isolation resistor 78. Power supply circuit 74 is coupled with ground potential at ground locus 75. Power supply circuit 74 is coupled with positive supply terminal 84 So that power supply circuit 74 provides a positive supply signal to positive supply terminal 84. Negative supply terminal 86 is coupled to ground potential at ground locus 87. No negative supply signal is supplied to amplifier 72 by power supply circuit 74.

A current supply 96 is coupled with first circuit locus 71 via an isolation resistor 75 so that a current I may be injected into preamp apparatus 70 at first circuit locus 71 to establish a controlled voltage drop across magneto-resistive device 76 and isolation resistor 78. By controlling voltage drop across magneto-resistive device 76 and isolation resistors 75, 78, potential at first circuit locus 71 may be controlled. Isolation resistors 75, 78 cooperate to isolate magneto-resistive device 76 from noise sources that are external or internal with respect to preamplifier apparatus 70.

First circuit locus 71 is electrically adjacent to magneto-resistive device 76 and to positive signal input terminal 80 (as was true in preamplifier apparatus 40; FIG. 2). However, DC blocking capacitor 79 blocks DC from reaching positive signal input terminal 80. DC is therefore blocked from reaching internal components of amplifier 72 (not shown in FIG. 3). As a result, potential at the internal components of amplifier 72 may be maintained at a different DC level than the potential maintained at first circuit locus 71.

Preamplifier apparatus 72 is preferably configured as a product carried on a printed wiring board or as an integrated circuit on a chip, as indicated by a schematic chip boundary 98.

FIG. 4 is an electrical schematic diagram illustrating an equivalent circuit for a portion of the novel single supply preamplifier illustrated in FIG. 3. In FIG. 4, an equivalent circuit 100 represents a portion of a single supply preamplifier such as preamplifier apparatus 70 (FIG. 3). Equivalent circuit 100 includes a magneto-resistive device 102 coupled with a current source 104 via an isolation resistor 105. Magneto-resistive device 102 is coupled with ground potential at ground locus 107 via an isolation resistor 106. Magneto-resistive device 102 is akin to magneto-resistive device 76 (preamplifier apparatus 70; FIG. 3). Current source 104 is akin to current source 96 (preamplifier apparatus 70; FIG. 3). Isolation resistors 105, 106 are akin to isolation resistors 75, 78 (preamplifier apparatus 70; FIG. 3).

An inductor 108 is coupled to a circuit locus 109 between isolation resistor 105 and magneto-resistive device 102. Inductor 108 represents the inductance present in leads extending between amplifier 72 and magneto-resistive device 76 (preamplifier apparatus 70; FIG. 3). Leads between an amplifier and a magneto-resistive device are typically relatively long in preamplifier devices employed in storage disk read apparatuses. This is so because the mass of the read head is desirably kept to a minimum in order that the head can accelerate rapidly in moving to read data on a storage disc. The masses of the amplifier (e.g., amplifier 72, FIG. 3) and associated components, such as a signal source, power supply circuit, DC Blocking capacitors and isolation resistor (e.g., signal source 96, power supply circuit 74, capacitors 79, 81 and isolation resistor 78; FIG. 3) are preferably situated at a location remote from the reader head itself to avoid contributing to inertia of the reader head.

In equivalent circuit 100 (FIG. 4), a DC blocking capacitor 110 is connected between inductor 108 and an impedance 112. Impedance 112 is coupled with ground potential at ground locus 113. DC blocking capacitor 110 is akin to DC blocking capacitor 79 (preamplifier apparatus 70; FIG. 3). Impedance 112 represents the internal impedance presented by amplifier 72 to positive signal input terminal 80 (preamplifier apparatus 70; FIG. 3). An indication that impedance 112 is an internal impedance within an amplifier device is illustrated by a dotted-line representation of an amplifier device 120 in FIG. 4.

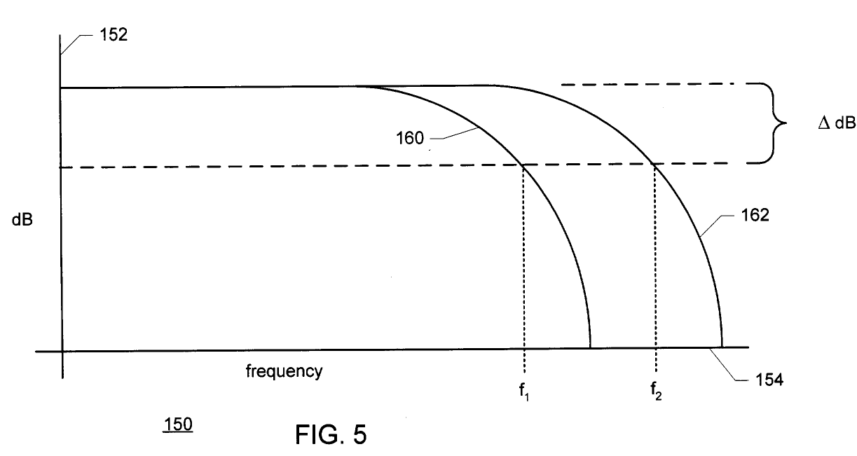

Inductance contributed by inductance in leads between a magneto-resistive device and an amplifier in a preamplifier apparatus results in a decrease, or “roll-off” of signal response of the preamplifier apparatus as frequency of signals traversing the leads increases (FIG. 5). The capability to isolate voltage across magneto-resistive device 76 at first circuit locus 71 from voltage at positive signal input terminal 80 in preamplifier apparatus 70 (FIG. 3) permits operation of preamplifier apparatus 70 so that response “roll off” occurs at a higher frequency than occurs in prior art single supply preamplifier apparatuses (e.g., preamplifier apparatus 40; FIG. 2). Operation of a reader apparatus at a higher frequency permits the head reader device to operate with a greater bandwidth. Higher signal frequency also permits data to be more tightly arranged or packed on a disk so that more data may be stored on the disk.

FIG. 5 is a graphic representation of the sensitivity responses of a prior art single supply preamplifiers and a novel single supply preamplifier configured according to the teachings of the present invention. In FIG. 5, a graphic representation 150 represents output signal strength from an amplifier (in decibels) plotted with respect to an axis 152, as a function of signal frequency plotted with respect to an axis 154. A first curve 160 represents a response curve of output signal strength (e.g. strength of signals appearing at output terminals 60, 62 of preamplifier apparatus 40; FIG. 2) as a function of signal frequency for a prior art single supply preamplifier apparatus (e.g., preamplifier apparatus 40; FIG. 2). A second curve 162 represents a response curve of output signal strength (e.g. strength of signals appearing at output terminals 90, 92 of preamplifier apparatus 70; FIG. 3) as a function of signal frequency for a single supply preamplifier apparatus configured according to the teaching of the present invention (e.g., preamplifier apparatus 70; FIG. 3). Acceptable performance for a preamplifier apparatus is typically expressed as a signal degradation less than a predetermined amount ΔdB as indicated in FIG. 5. An exemplary typical ΔdB in the telecommunications industry is 3 dB. Inspection of FIG. 5 reveals that output signals represented by response curve 160 (prior art preamplifier devices) degrade a maximum permitted ΔdB amount at a frequency f₁. Inspection of FIG. 5 also reveals that output signals represented by response curve 162 (preamplifier devices configured according to the teaching of the present invention) degrade a maximum permitted amount ΔdB at a frequency f₂. It is this decreasing, or “rolling off” of response curves from a maximum level toward zero that is the “roll off” of response referred to earlier in connection with describing the effect of inductor 108 (FIG. 4). Frequency f₂ is a higher frequency than frequency f₁, indicating that single supply preamplifier apparatuses configured according to the teaching of the present invention can operate at higher speeds than prior art single supply preamplifier apparatuses.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following claims:

I claim:

1. An apparatus for monitoring changes in a magnetic field using a magneto-resistive device situated in said magnetic field; the apparatus comprising a first input locus and a second input locus coupled with said magneto-resistive device; an amplifier means for amplifying electrical signals having a plurality of input terminals and a plurality of output terminals; a first input terminal of said plurality of input terminals being coupled with said first input locus; a first capacitor coupled in series between said first input locus and said first input terminal; a second input terminal of said plurality of input terminals being coupled with said second input locus; a second capacitor coupled in series between said second input locus and said second input terminal; the apparatus receiving a bias current at said first input locus; said bias current cooperating with said magneto-resistive element to affect electrical potential at said first input locus; said amplifier device presenting at least one output signal at said plurality of output terminals indicating changes in said magnetic field.

2. An apparatus for monitoring changes in a magnetic field using a magneto-resistive device situated in said magnetic field as recited in claim 1 wherein said amplifier means further has a plurality of supply terminals; and wherein the apparatus further comprises a power supply means for providing operating power for said amplifier means; said power supply means being coupled with a first supply terminal of said plurality of supply terminals; a second supply terminal of said plurality of supply terminals being coupled with ground potential.

3. An apparatus for monitoring changes in a magnetic field using a magneto-resistive device situated in said magnetic field as recited in claim 1 wherein said second input locus is coupled with ground potential.

4. An apparatus for monitoring changes in a magnetic field using a magneto-resistive device situated in said magnetic field as recited in claim 3 wherein the apparatus further comprises a fixed impedance coupled between said second input locus and ground potential.

5. An apparatus for monitoring changes in a magnetic field using a magneto-resistive device situated in said magnetic field as recited in claim 2 wherein said second input locus is coupled with ground potential.

6. An apparatus for monitoring changes in a magnetic field using a magneto-resistive device situated in said magnetic field as recited in claim 5 wherein the apparatus further comprises a fixed impedance coupled between said second input locus and ground potential.

7. An apparatus for reading information from a magnetic storage medium operated proximal to a magneto-resistive device; the apparatus comprising a first input locus and a second input locus coupled with said magneto-resistive device; an amplifier means for amplifying electrical signals having a plurality of input terminals and a plurality of output terminals; a first input terminal of said plurality of input terminals being coupled with said first input locus; a first capacitor coupled in series between said first input locus and said first input terminal; a second input terminal of said plurality of input terminals being coupled with said second input locus; a second capacitor coupled in series between said second input locus and said second input terminal; the apparatus receiving a bias current at said first input locus; said bias current cooperating with said magneto-resistive element to affect electrical potential at said first input locus; said amplifier device presenting at least one output signal at said plurality of output terminals indicating changes in said magnetic field.

8. An apparatus for reading information from a magnetic storage medium operated proximal to a magneto-resistive device as recited in claim 7 wherein said amplifier means further has a plurality of supply terminals; and wherein the apparatus further comprises a power supply means for providing operating power for said amplifier means; said power supply means being coupled with a first supply terminal of said plurality of supply terminals; a second supply terminal of said plurality of supply terminals being coupled with ground potential.

9. An apparatus for reading information from a magnetic storage medium operated proximal to a magneto-resistive device as recited in claim 7 wherein said second input locus is coupled with ground potential.

10. An apparatus for reading information from a magnetic storage medium operated proximal to a magneto-resistive device as recited in claim 9 wherein the apparatus further comprises a fixed impedance coupled between said second input locus and ground potential.

11. An apparatus for reading information from a magnetic storage medium operated proximal to a magneto-resistive device as recited in claim 8 wherein said second input locus is coupled with ground potential.

12. An apparatus for reading information from a magnetic storage medium operated proximal to a magneto-resistive device as recited in claim 11 wherein the apparatus further comprises a fixed impedance coupled between said second input locus and ground potential.

13. An amplifying apparatus for use with a magneto-resistive device situated in a magnetic field for monitoring changes in said magnetic field; the apparatus comprising a first input locus and a second input locus coupled with said magneto-resistive device; an amplifier means for amplifying electrical signals having a plurality of input terminals and a plurality of output terminals; a first input terminal of said plurality of input terminals being coupled with said first input locus; a first capacitor coupled in series between said first input locus and said first input terminal; a second input terminal of said plurality of input terminals being coupled with said second input locus; a second capacitor coupled in series between said second input locus and said second input terminal; the apparatus receiving a bias current at said first input locus; said bias current cooperating with said magneto-resistive element to affect electrical potential at said first input locus; said amplifier device presenting at least one output signal at said plurality of output terminals indicating changes in said magnetic field.

14. An amplifying apparatus for use with a magneto-resistive device situated in a magnetic field for monitoring changes in said magnetic field as recited in claim 13 wherein said amplifier means further has a plurality of supply terminals; and wherein the apparatus further comprises a power supply means for providing operating power for said amplifier means; said power supply means being coupled with a first supply terminal of said plurality of supply terminals; a second supply terminal of said plurality of supply terminals being coupled with ground potential.

15. An amplifying apparatus for use with a magneto-resistive device situated in a magnetic field for monitoring changes in said magnetic field as recited in claim 13 wherein said second input locus is coupled with ground potential.

16. An amplifying apparatus for use with a magneto-resistive device situated in a magnetic field for monitoring changes in said magnetic field as recited in claim 15 wherein the apparatus further comprises a fixed impedance coupled between said second input locus and ground potential.

17. An amplifying apparatus for use with a magneto-resistive device situated in a magnetic field for monitoring changes in said magnetic field as recited in claim 14 wherein said second input locus is coupled with ground potential.

18. An amplifying apparatus for use with a magneto-resistive device situated in a magnetic field for monitoring changes in said magnetic field as recited in claim 17 wherein the apparatus further comprises a fixed impedance coupled between said second input locus and ground potential.
